(19) United States
(12) Patent Application Publication
(10) Pub. No.: US 2024/0141478 A1
(43) Pub. Date: May 2, 2024

(54) WEB COATING COOLING DRUM WITH TURBULATORS FOR HIGH FLUX METALLIC LITHIUM DEPOSITION

(71) Applicant: Applied Materials, Inc., Santa Clara, CA (US)

(72) Inventors: Timothy KLEINER, Santa Clara, CA (US); David Masayuki Ishikawa, Mountain View, CA (US); Kenneth Moyers, Santa Clara, CA (US); Sumedh Dattatraya Acharya, Bangalore (IN); Visweswaren Sivaramakrishnan, Cupertino, CA (US)

(21) Appl. No.: 18/498,239

(22) Filed: Oct. 31, 2023

(30) Foreign Application Priority Data
Oct. 31, 2022 (IN) 202241061815

(51) Int. Cl. C23C 14/54; C23C 14/24; C23C 14/56; H01M 4/04; H01M 4/1395

(52) U.S. Cl. CPC C23C 14/541; C23C 14/24; C23C 14/562; H01M 4/0423; H01M 4/1395

(57) ABSTRACT

The present disclosure relates to vapor deposition systems and methods. In one embodiment, a drum for vapor deposition is provided. The drum includes a shell having gas slits and a cooling drum. The cooling drum includes an exterior region, an interior region, a first fluid channel partially defined by the exterior region and the interior region, and a first inlet. The first fluid channel forms a helical channel around a central axis of the cooling drum. The first inlet is in fluid communication with a first outlet by the first fluid channel.

### CROSS-REFERENCE TO RELATED APPLICATIONS

This application claims benefit of Indian Patent Application No. 202241061815, filed Oct. 31, 2022, the entirety of which is herein incorporated by reference.

### BACKGROUND

### Field

Implementations described herein generally relate to metal electrodes, more specifically lithium-containing anodes, high performance electrochemical devices, such as primary and secondary electrochemical devices, including the aforementioned lithium-containing electrodes, and methods for fabricating the same.

### Description of the Related Art

Lithium (Li) ion batteries have played a vital role in the development of current generation mobile devices, microelectronics, and electric vehicles. A typical Li-ion battery is made of a positive electrode (cathode), a negative electrode (anode), an electrolyte to conduct ions, a porous separator membrane (electrical insulator) between the two electrodes to keep them physically apart, and the packaging.

Methods of depositing lithium on substrates, such as large flexible substrates can be temperature sensitive and cause the formation of wrinkles and other defects. The substrate may be guided on and supported by a rotatable coating drum with a curved drum surface. A vapor may be deposited on the substrate while the substrate moves on the curved drum surface of the rotatable drum past the evaporation source or sources. Drums may be used to maintain high heat transfer rate and to control temperature of the substrates by cooling and pressurizing a backside of the substrate using high pressure to maintain a uniform gap height between the substrate and the curved drum surface. Low web tension can be used for wide thin film substrates due to particles, film stress, or misalignment causing machine-direction wrinkles.

Therefore, there is a need for apparatuses and methods to maintain low pressure and enhanced substrate cooling to improve throughput.

### SUMMARY

The present disclosure relates to vapor deposition systems and methods. In one embodiment, a drum for vapor deposition is provided. The drum includes a shell having gas slits and a cooling drum. The cooling drum includes an exterior region, an interior region, a first fluid channel partially defined by the exterior region and the interior region, and a first inlet. The first fluid channel forms a helical channel around a central axis of the cooling drum. The first inlet is in fluid communication with a first outlet by the first fluid channel.

In one embodiment, a roll-to-roll deposition system is provided. The roll-to-roll deposition system includes an evaporation unit, a plurality of tension rollers, and a drum. The drum is disposed between the plurality of tension rollers and the evaporator unit. The drum includes a shell having gas slits, and a cooling drum. The cooling drum includes an exterior region, an interior region, a first fluid channel, and a first inlet. The first fluid channel is partially defined by the exterior region and the interior region. The first fluid channel forms a helical channel around a central axis of the cooling drum. The first inlet in fluid is in communication with a first outlet by the first fluid channel.

In one embodiment, a method of applying an anode material to a substrate is provided. The method includes supplying a coolant to a drum. The drum includes a shell, and a cooling drum disposed radially inward of the shell. The cooling drum has a first fluid channel. The first fluid channel is partially defined by an exterior region of the cooling drum and an interior region of the cooling drum, the first fluid channel forms a helical channel around a central axis of the cooling drum. The method also includes flowing coolant through the first fluid channel, flowing a gas through a cavity between the shell and the cooling drum, rolling a substrate onto the shell, and evaporating as anode material onto the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic cross-sectional view of one implementation of an energy storage device incorporating an anode electrode structure, according to some embodiments described herein.

FIG. 2 illustrates a cross-sectional view of one implementation of a dual-sided anode electrode structure, according to some embodiments described herein.

FIG. 3 illustrates a schematic sectional view of an evaporation source for depositing an evaporated material on a substrate, according to some embodiments described herein.

FIG. 4A shows a schematic view of a roll-to-roll unit incorporating a drum, according to some embodiments described herein.

FIG. 4B illustrates an internal geometry of a channel region of a drum, according to some embodiments described herein.

FIG. 4C is a schematic cross sectional view of a drum, according to some embodiments described herein.

FIG. 5A illustrates a schematic view of the inside of a fluid channel of a drum, according to some embodiments described herein.

FIG. 5B illustrates a schematic view of the inside of the fluid channel of FIG. 5A, according to some embodiments described herein.

FIG. 6 illustrates a flow diagram of a method of cooling a substrate while using a roll-to-roll deposition system incorporating a drum, according to some embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Vapor deposition systems for coating a web substrate being guided on a rotatable coating drum are referred to herein as roll-to-roll (R2R) deposition systems. As described herein, flexible substrates can be considered to include among other things, films, foils, webs, strips of plastic material, metal, paper, or other materials. Typically, the terms “web,” “foil,” “strip,” “substrate” and the like are used synonymously.

Energy storage devices, for example, Li-ion batteries, typically include a positive electrode (e.g., cathode) and a negative electrode (e.g., anode) separated by a polymer separator with a liquid electrolyte. Solid-state batteries also typically include a positive electrode and a negative electrode but replace both the polymer separator and the liquid electrolyte with an ion-conducting material. Lithium is deposited onto substrates by evaporating molten lithium and condensing lithium vapor onto a substrate, such as a graphite coated copper foils, copper foils, or copper coated polymer films. The substrates are maintained below a certain temperature as the lithium is being deposited on the front side of the substrates. Maintaining the temperature can include cooling a back side of a substrate, by venting gas between the drum surface that is supporting the substrate and the substrate. The deposition rate of the lithium on the substrate is limited by the rate of cooling on the backside of the substrate. The cooling gas is selected such that it does not react with lithium. In some embodiments, the cooling gas can be or include argon, helium, ora combination thereof.

In addition to providing the cooling gas to the back side of the substrate, a uniform gap distance between the substrate and the drum surface is typically maintained. Conventional solutions for retaining the substrate included high tension (e.g. greater than 100 Newton per meter web tension) and mechanical solutions, such as disposing retaining nip rollers about the drum to retain the substrate to the drum and to prevent the substrate from ballooning off of the drum with the application of gas and as the substrate is thermally expanding. These solutions can lead to web edge damage and coat peeling. It has been discovered that the use of coulombic electrostatic clamping retains substrates to the drum and maintains uniform gap between the substrate and the drum surface.

In some embodiments, the substrate is a flexible substrate that is supported on the curved drum surface of a rotatable drum during the deposition. Specifically, the substrate may be moved past a plurality of nozzles depositing the material on the substrate on the curved drum surface of the rotatable drum.

The substrate may be a flexible substrate, for example, a flexible polymer material or a flexible metal foil, more particularly a copper foil or a copper-carrying foil, e.g., a foil that is coated with copper on one or both sides thereof. The substrate may have a thickness of 50 μm or less, particularly 20 μm or less, e.g., about 8 μm. In some embodiments, the substrate may be a thin copper foil having a thickness in a sub 20-μm range (e.g. 4 microns thick, or 6 microns thick).

According to some embodiments, which can be combined with other embodiments described herein, an anode of a battery is manufactured, and the flexible substrate includes copper or a copper alloy or consists of copper or a copper alloy. According to some implementations, the web may further contain graphite, silicon, silicon oxide, or any combination thereof. For example, the lithium may pre-lithiate the layer including graphite, silicon, and/or silicon oxide.

The deposition of a metal, e.g., lithium, on a flexible substrate, e.g., on a copper substrate, by evaporation may be used for the manufacture of batteries, such as Li-batteries. For example, a lithium layer may be deposited on a thin flexible substrate for producing the anode of a battery. After assembly of the anode layer stack and the cathode layer stack, optionally with an electrolyte and/or separator there between, the manufactured layer arrangement may be rolled or otherwise stacked to produce the Li-battery.

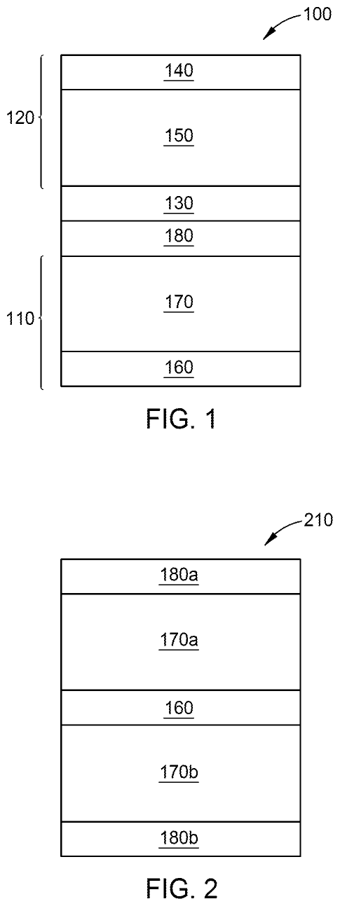

FIG. 1 illustrates a schematic cross-sectional view of one implementation of an energy storage device 100 incorporating an anode electrode structure 110 formed according to implementations described herein. The anode electrode structure 110 includes an anode film 170 having the one or more ceramic protective film(s) formed thereon. The energy storage device 100 may be a solid-state energy storage device or a lithium-ion based energy storage device. The energy storage device 100, even though shown as a planar structure, may also be formed into a cylinder by rolling the stack of layers; furthermore, other cell configurations (e.g., prismatic cells, button cells, or stacked electrode cells) may be formed. The energy storage device 100 includes the anode electrode structure 110 and a cathode electrode structure 120, optionally with an electrolyte or polymer separator 130 positioned there between. The cathode electrode structure 120 includes a cathode current collector 140 and a cathode film 150.

The one or more protective film(s) 180 include one or more ceramic materials. The ceramic material may be an oxide, a nitride, or an electrolyte soluble fluoride or carbonate. In one implementation, the one or more ceramic protective film(s) 180 includes a material selected from, for example, aluminum oxide (Al₂O₃), lithium fluoride (LiF), lithium carbonate (Li₂CO₃), aluminum oxynitride, aluminum nitride (AlN, aluminum deposited in a nitrogen environment), aluminum hydroxide oxide ((AlO(OH)) (e.g., diaspore ((α-AlO(OH))), boehmite (γ-AlO(OH)), or akdalaite (5Al2O3·H2O)), calcium carbonate (CaCO3), titanium dioxide (TiO2), SiS2, SiPO4, silicon oxide (SiO2), zirconium oxide (ZrO2), hafnium oxide (HfO2), MgO, TiO2, Ta2O5, Nb2O5, LiAlO2, BaTiO3, boron nitride (BN), ion-conducting garnet, ion-conducting perovskite, ion-conducting anti-perovskites, porous glass ceramic, and the like, or combinations thereof. In certain implementations, the one or more ceramic protective film(s) 180 are deposited using evaporation techniques as described herein.

In certain implementations, each layer of the one or more protective film(s) 180 is a coating or a discrete film having a thickness in a range of about 1 nanometer to about 3,000 nanometers (e.g., in the range of about 10 nanometers to about 600 nanometers; in the range of about 50 nanometers to about 100 nanometers; in the range of about 50 nanometers to about 200 nanometers; in the range of about 100 nanometers to about 150 nanometers).

The cathode electrode structure 120 includes the cathode current collector 140 with the cathode film 150 formed on the cathode current collector 140. It should be understood that the cathode electrode structure 120 may include other elements or films.

The current collectors 140, 160, on the cathode film 150 and the anode film 170, respectively, can be identical or different electronic conductors. In certain implementations, at least one of the current collectors 140, 160 is a flexible substrate. The flexible substrate may be a CPP film (i.e., a casting polypropylene film), an OPP film (i.e., an oriented polypropylene film), or a PET film (i.e., a polyethylene terephthalate film). Alternatively, the flexible substrate may be a pre-coated paper, a polypropylene (PP) film, a PEN film, a polylactic acid (PLA) film, or a PVC film. Examples of metals that the current collectors 140, 160 may be comprised of include aluminum (Al), copper (Cu), zinc (Zn), nickel (Ni), cobalt (Co), manganese (Mn), chromium (Cr), stainless steel, clad materials, alloys thereof, and a combination thereof. In one implementation, at least one of the current collectors 140, 160 is perforated. In one implementation, at least one of the current collectors 140, 160 includes a polymer substrate (e.g., polyethylene terephthalate (“PET”) coated with a metallic material. In one implementation, the anode current collector 160 is a polymer substrate (e.g., a PET film) coated with copper. In another implementation, the anode current collector 160 is a multi-metal layer on a polymer substrate. The multi-metal layer can be combinations of copper, chromium, nickel, alloys thereof, or any combination thereof. In one implementation, the anode current collector 160 is a multi-layer structure that includes a copper-nickel cladding material. In one implementation, the multi-layer structure includes a first layer of nickel or chromium, a second layer of copper formed on the first layer, and a third layer including nickel, chromium, or both formed on the second layer. In one implementation, the anode current collector 160 is nickel coated copper. In one implementation, the anode current collector 160 is graphite coated copper. Furthermore, current collectors may be of any form factor (e.g., metallic foil, sheet, or plate), shape and micro/macro structure.

In one implementation, the cathode current collector 140 is aluminum. In another implementation, the cathode current collector 140 can be or include aluminum deposited on a polymer substrate (e.g., a PET film). The cathode current collector 140 may have a thickness below 50 μm, more specifically, 5 μm or, even more specifically 2 μm. The cathode current collector 140 may have a thickness from about 0.5 μm to about 20 μm (e.g., from about 1 μm to about 10 μm; from about 2 μm to about 8 μm; or from about 5 μm to about 10 μm). In one implementation, the anode current collector 160 is copper. In one implementation, the anode current collector 160 is stainless steel. In one implementation, the anode current collector 160 has a thickness of less than 50 μm, more specifically, less than or about 5 μm or, even more specifically less than or about 2 μm. In one implementation, the anode current collector 160 has a thickness from about 0.5 μm to about 20 μm (e.g., from about 1 μm to about 10 μm; from about 2 μm to about 8 μm; from about 6 μm to about 12 μm; or from about 5 μm to about 10 μm).

The cathode film 150 or cathode may be any material compatible with the anode and may include an intercalation compound, an insertion compound, or an electrochemically active polymer.

The anode electrode structure 110 includes the anode current collector 160 with the anode film 170 formed on the anode current collector 160. The anode electrode structure 110 contains the one or more ceramic protective film(s) 180.

In some implementations, the anode film 170 is constructed from lithium metal, lithium metal foil or a lithium alloy foil (e.g., lithium aluminum alloys or lithium tin alloys), or a mixture of a lithium metal and/or lithium alloy and materials such as carbon (e.g., coke, graphite), nickel, copper, tin, indium, silicon, oxides thereof, or any combination thereof. The anode film 170 can be or include one or more intercalation compounds containing lithium or insertion compounds containing lithium. In certain implementations, the anode film is a lithium metal film. In certain implementations, wherein the anode film 170 can be or contain lithium metal, the lithium metal may be deposited using the methods described herein.

In some implementations, the anode film 170 can be or contain graphite, silicon, or any combination thereof. The anode film 170 can be or contain one or more carbonaceous materials, for example, natural graphite or artificial graphite, partially graphitized or amorphous carbon, petroleum, coke, needle coke, and various mesophases, silicon-containing graphite, silicon, nickel, copper, tin, indium, aluminum, silicon, oxides thereof, combinations thereof, or a mixture of a lithium metal and/or lithium alloy and materials such as carbon, for example, coke or graphite, nickel, copper, tin, indium, aluminum, silicon, oxides thereof, or combinations thereof. In one example, the anode film 170 can be or contain silicon-graphite. In another example, the anode film 170 can be or contain graphite.

In some implementations where the anode film 170 can be or contain graphite, silicon, or silicon-graphite, the anode film 170 has a layer of lithium formed on the surface of the anode film 170. The layer of lithium metal can have a thickness from about 20 μm to about 50 μm. The layer of lithium can be a pre-lithiation layer.

In one implementation, the anode film 170 has a thickness from about 10 μm to about 200 μm (e.g., from about 1 μm to about 100 μm; from about 10 μm to about 30 μm; from about 20 μm to about 30 μm; from about 1 μm to about 20 μm; or from about 50 μm to about 100 μm).

In some embodiments, the polymer separator 130 is a separator, the separator is a porous polymeric ion-conducting polymeric substrate. In one implementation, the porous polymeric substrate is a multi-layer polymeric substrate. In certain implementations, the porous polymeric substrate has a porosity in the range of about 20% to about 80% (e.g., in the range of about 28% to about 60%). The porous polymeric substrate may have an average pore size in the range of about 0.02 μm to about 5 μm (e.g., about 0.08 μm to about 2 μm). In certain implementations, the porous polymeric substrate has a Gurley Number in the range of about 15 seconds to about 150 seconds. The porous polymeric substrate may be or contain one or more polyolefin polymers. Examples of suitable polyolefin polymers include polypropylene, polyethylene, or combinations thereof. In at least one aspect, the porous polymeric substrate is a polyolefin membrane. In some aspect, the polyolefin membrane is a polyethylene membrane or a polypropylene membrane.

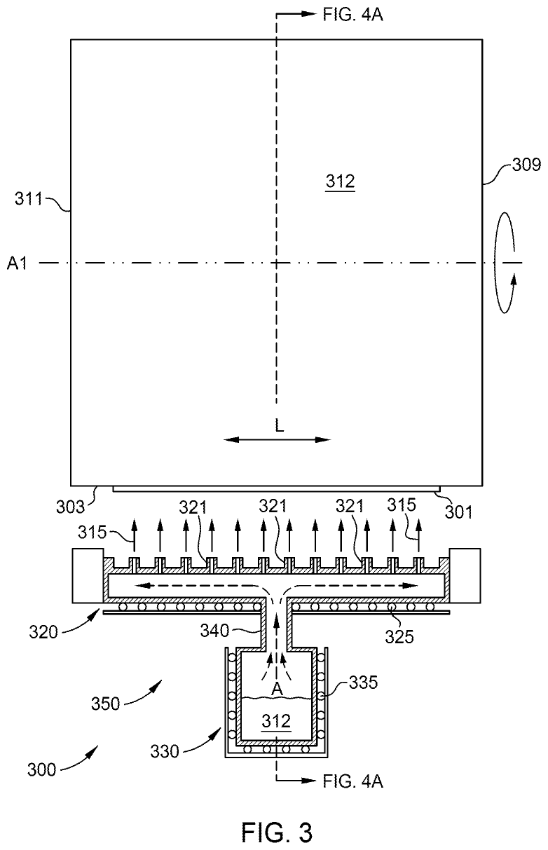

FIG. 2 illustrates a cross-sectional view of one implementation of a dual-sided anode electrode structure 210 formed according to one or more implementations described herein. The dual-sided anode electrode structure 210 includes the anode current collector 160 with the anode film 170a, 170b (collectively 170) formed on opposing sides of the anode current collector 160. The dual-sided anode electrode structure 210 further includes one or more protective film(s) 180a, 180b (collectively 180) formed on anode films 170a, 170b respectively.

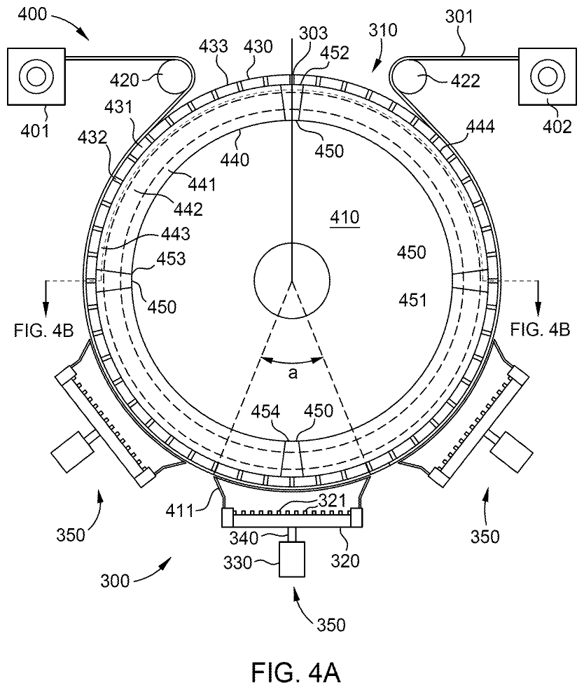

FIG. 3 is a schematic sectional view of a vapor deposition apparatus 300 incorporating a drum 310. The vapor deposition apparatus 300 may be a roll-to-roll deposition system for coating a flexible substrate, e.g., a foil or polymer substrate. The substrate to be coated may have a thickness of 50 μm or less, particularly 20 μm or less, or even 6 μm or less. For example, a metal foil or a flexible metal-coated foil may be coated in the vapor deposition apparatus. In some implementations, a substrate 301 is a thin copper foil or a thin aluminum foil having a thickness below 30 μm, e.g., 6 μm or less. The substrate could also be a thin metal foil (e.g., a copper foil) coated with graphite, silicon, silicon oxide, or any combination thereof, e.g., in a thickness of 150 μm or less, particularly 100 μm or less, or even down to 50 μm or less. According to some implementations, the web may further contain graphite, silicon, silicon oxide, or any combination thereof. For example, the lithium may pre-lithiate the layer including graphite, silicon, silicon oxide, or any combination thereof.

In a roll-to-roll deposition system, the substrate 301 may be unwound from a storage spool, at least one or more material layers may be deposited on the substrate while the substrate 301 is guided on the drum 310.

The drum 310 includes a curved face 303 of the drum 310, a central axis A1, a first face 311, and a second face 309 opposite the first face 311. The drum 310 is rotatable about the central axis A1.

The vapor deposition apparatus 300 includes an evaporation unit 350 for depositing an evaporated material on the substrate 301 according to embodiments described herein. The evaporation unit 350 includes an evaporation crucible 330 for heating a solid or liquid source material 312 to a temperature above the evaporation temperature or sublimation temperature of the source material 312, such that the source material 312 evaporates. The evaporation crucible 330 may include an inner volume acting as a material reservoir for accommodating the source material 312 in a solid and/or liquid state, and a first heater 335 for heating the inner volume of the evaporation crucible, such that the source material 312 evaporates. For example, the source material 312 may be a metal, particularly lithium, and the first heater 335 may be configured for heating the inner volume of the crucible to a temperature of about 180° C. or greater, particularly about 215° C. or greater, or about 400° C. or greater.

The evaporation unit 350 further includes a vapor distributor 320 with a plurality of nozzles 321 for directing the material evaporated in the evaporation crucible toward a substrate 301, such that a coating is deposited on the substrate 301. The vapor distributor 320 may include an inner volume that is in fluid communication with the inner volume of the evaporation crucible 330, such that the evaporated material can stream from the inner volume of the evaporation crucible 330 into the inner volume of the vapor distributor 320 through a vapor conduit 340, e.g., along a linear connection tube or passage. The plurality of nozzles 321 may be configured to direct the evaporated material from the inner volume of the vapor distributor 320 toward the substrate 301.

In some embodiments, the vapor distributor 320 may be a vapor distribution showerhead having the plurality of nozzles arranged in a 1-dimensional or 2-dimensional pattern for directing the evaporated material toward the substrate.

The evaporation crucible 330 is in fluid connection with the vapor distributor 320 via the vapor conduit 340 that extends from the evaporation crucible 330 to the vapor distributor 320 in a conduit length direction A. During evaporation, the vapor distributor 320 is typically provided at a second temperature that is higher than a first temperature inside the evaporation crucible 330 in order to prevent a material condensation on inner wall surfaces of the vapor distributor.

The evaporation unit 350 may further include a second heater 325 for heating an inner volume of the vapor distributor. The first heater 335 and the second heater 325 can be individually controlled. For example, the first heater 35 may be configured to heat the evaporation crucible to a first temperature and the second heater 325 may be configured to heat the vapor distributor to a second temperature different from the first temperature, particularly above the first temperature. During the vapor deposition, the inner volume of the vapor distributor is typically hotter than the inner volume of the evaporation crucible, in order to prevent a condensation of the evaporation material on inner walls of the vapor distributor. On the other hand, a major part of the inner volume of the evaporation crucible is to be maintained around the evaporation temperature of the source material 312 (i.e., slightly below or slightly above the evaporation temperature), in order to allow the source material 312 to evaporate a bit at a time at a predetermined evaporation rate.

In some embodiments, which can be combined with other embodiments described herein, the plurality of nozzles 321 may be arranged in a plurality of nozzle rows extending in a row direction L and arranged next to each other in the circumferential direction T, wherein the row direction L may essentially correspond to an axial direction of the drum 310. Accordingly, the vapor distributor 320 provides an area showerhead having a plurality of nozzles arranged in a two-dimension array for reducing the heat load per area on the substrate 301 supported on the curved face 303.

The substrate 301 is retained on the curved face 303 using an electrostatic clamping high voltage electrode and dielectric coating incorporated within the drum 310. Depending on the substrate type or material, the electrostatic clamping electrode and dielectric coating can be integrated in the drum 310 in various implementations.

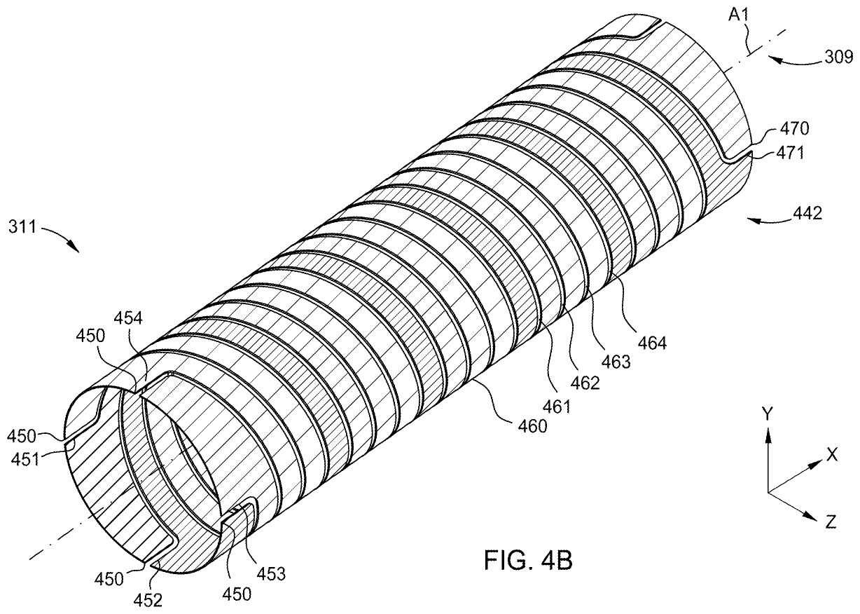

FIG. 4A shows a schematic view of a roll-to-roll unit 400 viewed along the central axis A1 of the drum 310 according to embodiments of the present disclosure. The roll-to-roll unit 400 may include an evaporation unit or several evaporation sources according to any of the embodiments described herein, such as the evaporation unit 350 described relative to FIG. 3.

The roll-to-roll unit 400 includes the substrate support being the curved face 303 of the drum 310 for supporting the substrate 301 during the deposition. The substrate 301 is supplied from a supply reel 401, to the drum 310 where the material 315 is deposited on the substrate 301. Once deposited, the substrate 301 travels to the end reel 402. The substrate 301 is wound on the end reel 402. Alternatively, the substrate 301 may continue onto other process units for additional processing, for example, additional deposition and/or coating in further apparatuses.

The plurality of nozzles 321 of the evaporation unit 350 are directed toward the curved face 303, and the roll-to-roll unit 400 is configured to move the substrate 301 on the curved face 303 past the evaporation unit 350. In some embodiments, several evaporation sources as described herein may be arranged one after the other in the circumferential direction T around the rotatable coating drum 310, such that the substrate can be subsequently coated by several evaporation sources. Different coating materials can be deposited on the substrate, or one thicker coating layer of the same coating material can be deposited on the substrate by the evaporation sources.

In some embodiments, which can be combined with other embodiments described herein, the roll-to-roll unit 400 further includes an edge exclusion shield 411 extending from the roll-to-roll unit 400 toward the curved face 303 of the drum 310.

The edge exclusion shield 411 masks areas of the substrate 301 not to be coated, e.g., for masking lateral edge areas of the substrate that are to be kept free of coating material. For example, the edge exclusion shield 411 may be configured to mask two opposing lateral edges of the substrate 301.

The edge exclusion shield 411 may extend along the curved face 303 of the drum 310 in the circumferential direction T, following a curvature of the curved face 303. Accordingly, a width D of a gap between the curved face 303 and the edge exclusion shield 411 can be kept small (e.g., 2 mm or less) and essentially constant along the circumferential direction T, such that the edge exclusion accuracy can be improved and sharp and well-defined coating layer edges can be deposited on the substrate 301.

As it is schematically depicted in FIG. 4A, the roll-to-roll unit 400 includes a plurality of tension rollers. In some embodiments, the roll-to-roll unit 400 includes a first tension roller 420 and a second tension roller 422 according to some embodiments. The first tension roller 420 receives the substrate 301 from the supply reel 401 and aids in keeping tension on the substrate 301 while the substrate 301 travels over the drum 310. The substrate 301 travels to the second tension roller 422 from the drum 310. The second tension roller 422 aids in keeping tension on the substrate 301 while the substrate 301 is rolled on the drum 310. The substrate 301 travels from second tension roller 422 to the end reel 402.

As it is schematically depicted in FIG. 4A, the evaporation unit 350 includes the evaporation crucible 330 for evaporating a material, the vapor distributor 320 with the plurality of nozzles 321 for directing the evaporated material toward the substrate 301 supported on the drum 310, and the vapor conduit 340 extending in a conduit length direction from the evaporation crucible 330 to the vapor distributor 320, providing a fluid connection between the evaporation crucible 330 and the vapor distributor 320. At least one nozzle or all nozzles 321 of the plurality of nozzles 321 may have a nozzle axis that extends in, or is essentially parallel to, the conduit length direction A. As is depicted in FIG. 3, the conduit length direction A may essentially correspond to a radial direction of the drum 310.

As it is schematically depicted in FIG. 4A, the drum 310 includes a shell 430 and a cooling drum 410. The shell 430 is disposed radially outward from the cooling drum 410. The substrate 301 translates across an exterior surface 433 of the shell 430. In some embodiments, the exterior surface 433 of the shell 430 is the curved surface of the drum 310. In some embodiments, the shell 430 includes a high thermal conductivity dielectric coating, such as yttria doped aluminum nitride, that isolates an invar or similar coefficient of thermal expansion-matched thin metal electrode connected to a high voltage (e.g. >600 volts) direct current power supply that enables the shell to act as an electrostatic chuck to hold the substrate 301 with a thin (e.g. <15 microns) gap between the exterior surface 433 and substrate 301.

The shell 430 and a curved exterior surface of the cooling drum 410 define a cavity 431. The cavity 431 may include narrow gas grooves spaced between textured mesas to allow a gas to pass between the shell 430 and the cooling drum 410. The gas then travels out of the cavity 431 through slits in the shell 430. In some embodiments that gas is pressurized to force the substrate 301 to travel over the shell 430 on an air cushion. In other embodiments the gas is used as a heat transfer medium, to cool the substrate 301 by allowing heat to flow unimpeded across the gap and into the fluid cooled shell 430. The gas, being at a higher pressure, and therefore higher thermal conductivity, enhances the transfer rate of thermal energy. The cavity 431 is defined by the shell 430 and the curved exterior surface 444 of the cooling drum 410. Within the cavity 431 are supports 432. The supports 432 extend from the curved exterior surface 344 of the cooling drum 410 to the shell 430. In some embodiments, the cooling drum 410, the supports 432, and the shell 430 are a monolithic single part, made through additive manufacturing, for example, metal additive manufacturing. In other words, the drum 310 is a monolithic drum. As in, the drum 310 is a single part formed by additive manufacturing. As in, the drum 310 is a single body formed by additive manufacturing. In some embodiments, portions of the drum 310 are formed by additive manufacturing. For example, the cooling drum 410 is a monolithic cooling drum formed by additive manufacturing.

The cooling drum 410 is partially defined by the curved exterior surface 444 and an interior surface 440. The cooling drum 410 includes an exterior region 443, a channel region 442, and an interior region 441. The exterior region 443, the channel region 442, and the interior region 441 are disposed between the curved exterior surface 444 and the interior surface 440. The cooling drum 410 is a single body. In other words, it is monolithic part. For example, the cooling drum 410 is a single 3D printed body. The cooling drum 410 is a metal drum with cooling channels (FIG. 4B) disposed within the channel region 442 of the cooling drum 410. The exterior region 443 is disposed between the curved exterior surface 444 and the channel region 442 of the cooling drum 410. In one or more embodiments, which can be combined with other embodiments, the exterior region 443 has a thickness between the curved exterior surface 444 and the channel region 442 of about 0.1 millimeter and about 5 millimeters, for example about 1.5 millimeters for selective laser melting (SLM) based additive manufacturing, which is sufficiently thick to reduce the risk of possible pores between the melt pools which causes a heat transfer fluid leak. When the exterior region 443 is less thick, greater thermal energy transfer rates can be achieved.

The channel region 442 is disposed between the exterior region 443 and the interior region 441. The channel region 442 is disposed radially inward of the exterior region 443 and radially outward of the interior region 441. In one or more embodiments, which can be combined with other embodiments, the channel region 442 has a thickness between the exterior region 443 and the interior region 441 of about 0.1 millimeter and about 5 millimeters, for example about 4 millimeters for selective laser melting (SLM) based additive manufacturing. The thickness is selected to facilitate de-powdering. In one or more embodiments, which may be combined with other embodiments, the thickness is about 1.3 millimeters for high resolution lithography printing which enhances local fluid velocity without excessively high pressure drop. The cross sectional area of the fluid channels 460 is influenced by the thickness of the channel region. Gradient optimization of the hydraulic diameter or cross sectional area of the fluid channels 460 convection heat transfer rate and can ensure thermal uniformity on the exterior of the cooling drum 410 and enhance deposition uniformity on the substrate 301.

The channel region 442 includes at least one or more inlets 450. While FIG. 4A illustrates the at least one or more inlets 450 including a first inlet 451, a second inlet 452, a third inlet 453, and a fourth inlet 454, other embodiments are contemplated. For example, an embodiment with a single first inlet 451, an embodiment with two inlets 450, with three inlets 450, with five inlets 450, with six or more inlets 450, but more inlets 450 are contemplated. The inlets 450 are connected to the fluid channels 460 (FIG. 4B).

The inlets 450 are disposed radially on or about the cooling drum 410. In some embodiments, the inlets 450 are disposed offset about equal angles from each other. For example, in embodiments with four inlets, the inlets 450 are angularly offset for each other by about 90°. In other words, the inlets 450 may be radially arrayed on the first face 311 and/or second face 309.

FIG. 4B illustrates an internal geometry of the channel region 442, according to some embodiments. whereas prior manufacturing methods were unable to create an internal helical structure within a part, various forms of additive manufacturing enable the cooling drum to have internal helix cavities as described herein.

The inlets 450 connect and are in fluid communication with the fluid channels 460. In some embodiment, the fluid channels 460 include a first fluid channel 461, a second fluid channel 462, a third fluid channel 463, and a fourth fluid channel 464. While only four fluid channels 460 are shown others numbers are contemplated. For example, one fluid channel 460, two fluid channels 460, three fluid channels 460, six fluid channels 460, or six or more fluid channels 460.

The first fluid channel 461 is connected and in fluid communication with the first inlet 451. The first inlet 451 is proximate to the first face 311. The first fluid channel 461 is partially defined by the exterior region 443 and the interior region 441 (FIG. 4A). The first fluid channel 461 forms a helical channel around the central axis A1 of the cooling drum 410 (FIG. 4A). The first fluid channel 461 connects and is connected to a first outlet 471 of at least one or more outlets 470. The first outlet 471 is disposed on the second face 309 of the cooling drum 410 (FIG. 4A).

The second fluid channel 462 is connected and in fluid communication with the second inlet 452. The second inlet 452 is proximate to the first face 311. The second fluid channel 462 is partially defined by the exterior region 443 and the interior region 441 (FIG. 4A). The second fluid channel 462 forms a helical channel around the central axis A1 of the cooling drum 410 (FIG. 4A). The second fluid channel 462 connects and is connected to a second outlet 472 of at least one or more outlets 470. The second outlet 472 is disposed on the second face 309 of the cooling drum 410 (FIG. 4A).

The third fluid channel 463 is connected and in fluid communication with the third inlet 453. The third inlet 453 is proximate to the first face 311. The third fluid channel 463 is partially defined by the exterior region 443 and the interior region 441 (FIG. 4A). The third fluid channel 463 forms a helical channel around the central axis A1 of the cooling drum 410 (FIG. 4A). The third fluid channel 463 connects and is connected to a third outlet 473 of at least one or more outlets 470. The third outlet 473 is disposed on the second face 309 of the cooling drum 410 (FIG. 4A).

The fourth fluid channel 464 is connected and in fluid communication with the fourth inlet 454. The fourth inlet 454 is proximate to the first face 311. The fourth fluid channel 464 is partially defined by the exterior region 443 and the interior region 441 (FIG. 4A). The fourth fluid channel 464 forms a helical channel around the central axis A1 of the cooling drum 410 (FIG. 4A). The fourth fluid channel 464 connects and is connected to a fourth outlet 474 of at least one or more outlets 470. The fourth outlet 474 is disposed on the second face 309 of the cooling drum 410 (FIG. 4A).

In some embodiments two of the inlets 450 are disposed on the first face 311 and two of the inlets 450 are disposed on the second face 309. In this embodiment, two of the outlets are disposed on the first face 311 and two of the outlets 470 are disposed on the second face 309. By having inlets and outlets on both faces 309, 311, the cooling drum can have opposing cooling fluid flows, achieving uniform cooling across the whole drum.

In some embodiments, the fluid outlets 470 of the fluid channels 460 are disposed proximate to the second face 309. In some embodiments, the fluid inlets 450 of the fluid channels 460 are disposed proximate to the first face 311.

The fluid outlets 470 are disposed radially on the cooling drum 410. In some embodiments, the fluid outlets 470 are disposed offset about equal angles from each other. For example, in embodiments with four outlets, the fluid outlets 470 are angularly offset for each other by about 90°. In other words, the fluid outlets 470 may be radially arrayed on the first face 311 and/or second face 309.

In some embodiments, the fluid channels 460 have uniform rotations per unit length. For example, the fluid channels 460 form a rotation about the central axis A1 for every 100 millimeters along the central axis A1. In other words, for every 800 millimeters of central axis A1, each fluid channel 461, 462, 463, 464, will form between about 1 and about 20 rotations about central axis A1. In other embodiments, the fluid channels 460 have varying rotations per unit length. For example, the number of rotations per unit length about the central axis A1 will increase or decrease along the central axis A1.

The fluid channels 460 are offset from each other. For example, the first fluid channel 461 is offset form the second fluid channel 462. The fluid channels 460 are in part radially offset such that they do not cross each other. In other words, the inlets 450 and distributed radially around the central axis A1 so that the fluid channels 460 are radially offset from one another in an equal distribution.

FIG. 4C is a partial schematic cross sectional view of the drum 310 taken along 4C-4C of FIG. 4B according to some embodiments. As shown, each fluid channel 460 forms parallel helical channels in the cooling drum 410. As shown the substrate 301 receives gas from a plurality of gas slits 480. The slits 480 are openings in the exterior surface 433 of the shell 430. The gas is supplied to the cavity 431 by a gas inlet 481. The gas inlet 481 is disposed on the first face 311 according to some embodiments. In some embodiments there are multiple gas inlets 481. In some embodiments, there are gas inlets on the second face 309. In some embodiments there are gas inlets on both the first face 311 and second face 309.

As the substrate 301 receives thermal energy during an operation, the thermal energy is transferred from the substrate to the gas. The thermal energy is then transferred from the gas to the exterior surface 444 of the cooling drum 410. To further remove the thermal energy from the substrate 301, the coolant is flowed through the fluid channels 460 to maintain the substrate 301 at a temperature lower than 180.5° C., which is about the melting point of lithium. More specifically, maintain the substrate 301 at a temperature lower than 70° C. which is the glass transition, or softening temperature, of polymer binders in some anodes. For example, below 10° C. which is the typical operating set point of commercially available water-glycol heat exchangers. For example, below −30° C. for high throughput lithium web coating when using silicone oil heat exchangers.

The helical shape of the fluid channels 460 enhances, via secondary circulation, the amount of thermal energy that can be removed by the coolant. The helix design accomplished by the additive manufacturing methods allows for a distance 483 to be smaller between the substrate 301 and the fluid channels 460. For example the distance 483 between the fluid channels 460 disposed in the channel region 442 and the substrate 301 is between about 1 millimeter and about 10 millimeters. The distance 483 between the between the fluid channels 460 disposed in the channel region 442 and the substrate 301 includes the radial thickness of the exterior region 443, the radial thickness of the cavity 431, the radial thickness of the shell 430, and any gap formed by a gas cushion 484 between the substrate 301 and the shell. The gas cushion 484 has a thickness defined by a radial thickness between the shell 430 and the substrate 301. In some embodiments, the gas cushion has a thickness of between about 1 micrometer and 110 micrometers, for example less than 80 micrometers.

In some embodiments, the substrate 301 translates along the shell 430 and is not separated by a gas cushion. When not separated by a gas cushion, the shell 430 further enhances removal of thermal energy by conductive heat transfer. Therefore by making the whole drum 310 by additive manufacturing of a material with a high thermal energy transfer rate, greater cooling can be accomplished. For example, by forming the drum of aluminum, copper, a copper alloy, an aluminum alloy, a material aluminum, and/or a material comprising copper, the substrate 301 can be cooled more efficiently. Other materials with thermal energy transfer coefficients that increase the transfer rate of heat from the substrate 301 to the cooling drum 410 are also contemplated.

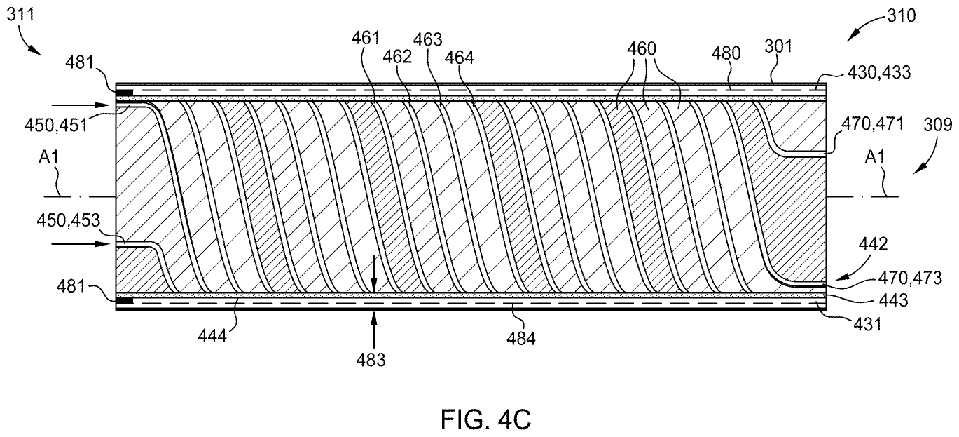

FIGS. 5A and 5B illustrate schematic views of the inside of a fluid channel 460 according to some embodiments. The fluid channels 460 include surface features 501. FIG. 5A illustrates a schematic cross sectional view of the fluid channels 460 perpendicular to the flow of fluid, according to some embodiments.

The surface features 501 may be on the outer radial surface 503 between the exterior region 443 and the channel region 442. The surface features 501 may be on the inner radial surface 505 between the interior region 441 and the channel region 442. The surface features 501 may be on one or more side walls 507 in the channel region 442.

FIG. 5B illustrates a schematic cross sectional view of the fluid channels 460 according to some embodiments. The inner radial surface 505, outer radial surface 503, and the side walls 507 for an interior surface 510 of each of the fluid channels 460.

As shown in FIG. 5B, the fluid channels 460 have a rectangular shape according to some embodiments. In some embodiments, the fluid channels 460 have a trapezoid shape. In some embodiments, the fluid channels 460 have a circular shape. In some embodiments, the fluid channels 460 form porous gyroids.

The surface features 501 may be turbulators and/or a turbulating surface feature. For example, the surface features 501 may by gyroid shaped turbulators and/or a turbulating gyroid surface feature configured to prevent laminar flow. The use of additive manufacturing enables gyroid shaped high surface area periodic turbulating features to be added to interior surface 510 while keeping the distance the thermal energy must travel to a minimum. The metal additive manufacturing of the drum 310 to make porous three-dimensional gyroids that serve as heat exchanger turbulators integral to the cooling drum 410 enhances the cooling ability of the drum 310. The surface features 501 prevent a uniform gradient, in the L direction shown FIG. 3, from developing in the fluid channels 460 by causing the coolant flow velocity to accelerate. The acceleration is caused by reducing the hydraulic diameter or cross section area of the fluid channel 460. By increasing the wetted surface area participating in heat transfer through of gradient modulation of the surface features 501, there is an increase in heat transfer to the fluid due to heat extraction from the shell 430 along fluid channels 460 flow length. The surface features 501 enhance the cooling ability of the fluid channels 460 by compensating for increase in coolant flow temperature to provide uniform fluid channels 460 temperature, thereby forcing a uniform and larger temperature delta between the outer radial surface 503 and the exterior region 443. Turbulator geometry optimization reduces uniform coolant flow within the fluid channels, thus compensating for increasing oil temperature gradients. By reducing a thermal gradient within the cooling in the fluid channels, a drum surface temperature is more uniform, and substrate coating non-uniformity is minimized.

The surface features 501 enable the flow of coolant to be a non-laminar flow. For example, the surface features 501 enable the flow of coolant to have a Reynolds number between about 2300 and about 4000. For example, the surface features 501 enable the flow of coolant to have a Reynolds number between about 2300 and about 4000 when the coolant is flowed a velocity between about 0.5 meters per second and about 5 meters per second, for example 1 meter per second.

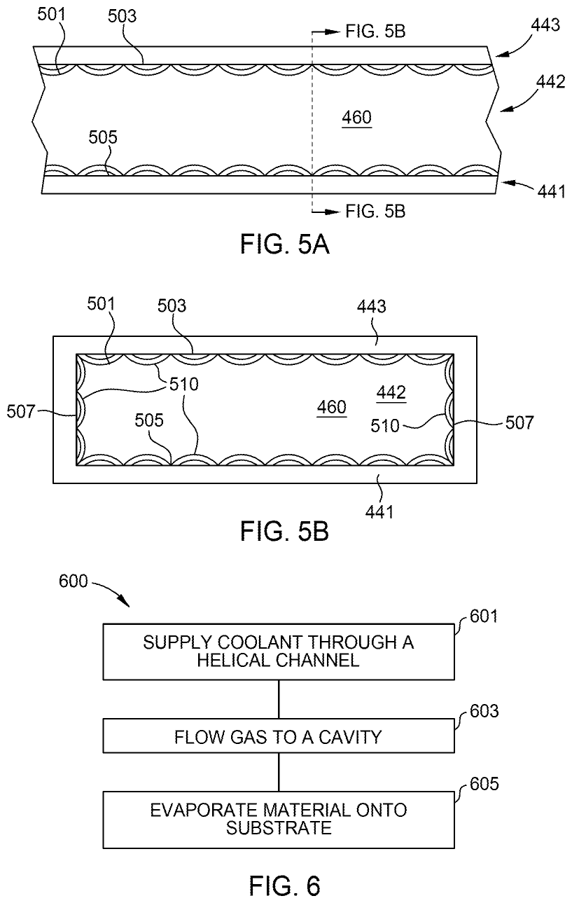

FIG. 6 illustrates a method 600 of cooling a substrate while using a roll-to-roll deposition system. At operation 601, a coolant is supplied to fluid channels 460 within the cooling drum 410 of the drum 310. As coolant flows through the first fluid channel 461, the coolant is turbulated to achieve uniform temperature distributions perpendicular to the flow of the coolant.

At operation 603, a gas is supplied to the cavity 431 of the drum 310. The gas may be an inert gas. For example, the gas is argon. For example, the gas is carbon dioxide. Other gases are contemplated.

At operation 605, the evaporation unit deposits a material onto the substrate 301. The material may be a lithium anode material. In some embodiments, the material may be a lithium material deposited onto a polymer substrate having a graphite layer disposed thereon for pre-lithiation.

The previously described embodiments of the present disclosure have many advantages including the following. The apparatus provided herein enables a 50,000 Watts per square meter heat load vacuum web coating with less than 35° C. temperature difference from drum surface to coolant channels and less than 4° C. transverse drum surface temperature non-uniformity. The disclosure provides for about 5 micron meters per minute to about 60 micron meters per minute, or greater than 60 micron meters per minute lithium deposition rate on transfer lamination and LIB anode webs. For example, the disclosure enables about 10 micron meters per minute to about 20 micron meters per minute lithium deposition rate on transfer lamination and LIB anode webs. However, the present disclosure does not necessitate that all the advantageous features and advantages need to be incorporated into every embodiment of the present disclosure.

The disclosure increases cooling channel heat transfer surface area and decreases boundary layer thickness to enable high deposition rate and low deposition thickness non-uniformity for improved coating economy and yield. The drum leverages metal additive manufacturing to make optimized porous three-dimensional gyroids that serve as heat exchanger turbulators integral to the cooling drum. A gas, such as an inert gas is distributed between cooling drum and shell. The cooling drum and/or shell can be additively manufactured. The cooling drum assemblies further include flowing fluids through the additive manufactured bodies for improved cooling rates. Turbulator geometry optimization reduces uniform coolant flow within the fluid channels, thus compensating for increasing oil temperature gradients. By reducing a thermal gradient within the cooling in the fluid channels, a drum surface temperature is more uniform, and substrate coating non-uniformity is minimized. Copper alloys or aluminum alloys may be utilized in the additive manufacturing process to form the drum. A drum for vapor deposition is shown and described herein. A vapor deposition apparatus with a drum is shown and described herein. A method for coating a substrate is shown and described herein.

While the foregoing is directed to embodiments, other and further embodiments may be devised without departing from the basic scope, and the scope is determined by the claims that follow.

What is claimed is:

1. A drum for vapor deposition, the drum comprising:
a shell having gas slits; and
a cooling drum comprising:
an exterior region;
an interior region;
a first fluid channel partially defined by the exterior region and the interior region, the first fluid channel forming a helical channel around a central axis of the cooling drum; and
a first inlet in fluid communication with a first outlet by the first fluid channel.

2. The drum of claim 1, wherein the cooling drum is a monolithic drum made of copper or aluminum alloy.

3. The drum of claim 1, wherein the first fluid channel comprises a turbulating surface feature.

4. The drum of claim 1, wherein the cooling drum further has a second fluid channel radially offset from the first cooling channel and partially defined by the exterior region and the interior region, the second fluid channel forming a helical channel around the central axis of the cooling drum.

5. The drum of claim 4, wherein the second fluid channel connects a second fluid inlet to a second fluid outlet.

6. The drum of claim 4, wherein the first inlet and a second inlet are disposed within a first face of the cooling drum.

7. The drum of claim 4, wherein the first inlet and second outlet are disposed within a first face of the cooling drum and a second inlet and first outlet are disposed within a second face of the cooling drum.

8. The drum of claim 1, wherein a distance between the shell and a curved surface of the exterior region of the cooling drum is between about 1 millimeter and about 5 millimeters.

9. The drum of claim 1, wherein the first inlet is disposed proximate a first face of the cooling drum and the first outlet is disposed proximate a second face of the cooling drum, the second face separated by a curved face of the cooling drum.

10. The drum of claim 1, wherein a thickness of the exterior region is less than 10 millimeters.

11. A roll-to-roll deposition system comprising:
an evaporation unit;
a plurality of tension rollers; and
a drum, disposed between the plurality of tension rollers and the evaporator unit, the drum comprising:
a shell having gas slits; and
a cooling drum comprising:
an exterior region;
an interior region;
a first fluid channel partially defined by the exterior region and the interior region, the first fluid channel forming a helical channel around a central axis of the cooling drum; and
a first inlet in fluid communication with a first outlet by the first fluid channel.

12. The roll-to-roll deposition system of claim 11, wherein the cooling drum is monolithic and made of copper or aluminum alloy.

13. The roll-to-roll deposition system of claim 11, wherein the cooling drum further has a second fluid channel radially offset from the first cooling channel and partially defined by the exterior region and the interior region, the second fluid channel forming a helical channel around the central axis of the cooling drum.

14. The roll-to-roll deposition system of claim 13, wherein the first inlet and second inlet are disposed on a first side of the cooling drum.

15. The roll-to-roll deposition system of claim 13, wherein the first inlet is disposed on a first side of the cooling drum and a second inlet is disposed on a second side of the cooling drum.

16. roll-to-roll deposition system of claim 11, wherein the first fluid channel comprises a turbulating surface feature.

17. A method of applying an anode material to a substrate comprising:
supplying a coolant to a drum, the drum comprising:
a shell; and
a cooling drum disposed radially inward of the shell and having a first fluid channel, the first fluid channel partially defined by an exterior region of the cooling drum and an interior region of the cooling drum, the first fluid channel forming a helical channel around a central axis of the cooling drum, the first fluid channel having a turbulating surface feature;
flowing coolant through the first fluid channel;
flowing a gas through a cavity between the shell and the cooling drum;
rolling a substrate onto the shell; and
evaporating as anode material onto the substrate.

18. The method of claim 17, wherein the coolant is flowed at a velocity of less than 1 meter per second.

19. The method of claim 17, wherein a gas cushion is formed between the substrate and the shell by the gas leaving the shell through a plurality of gas slits, the gas cushion being less than 15 micrometers.

20. The method of claim 17, wherein the flow of the coolant has a Reynolds number between about 2300 and about 4000.
